(19) United States
(12) Patent Application Publication
(10) Pub. No.: US 2024/0348230 A1
(43) Pub. Date: Oct. 17, 2024

(54) Resonator Device

(71) Applicant: SEIKO EPSON CORPORATION, Tokyo (JP)

(72) Inventor: Manabu KONDO, Matsumoto (JP)

(21) Appl. No.: 18/636,437

(22) Filed: Apr. 16, 2024

(30) Foreign Application Priority Data
Apr. 17, 2023 (JP) 2023-066999

(51) Int. Cl. H03H 9/10; H03H 9/05; H03H 9/19

(52) U.S. Cl. CPC H03H 9/1021; H03H 9/0533; H03H 9/0557; H03H 9/19

(57) ABSTRACT

A resonator device includes a container accommodating a resonator component and a base substrate on which the container is mounted. The base substrate includes a recess overlapping the container in plan view and forming a space with the container, a first bonding portion overlapping the container in plan view and bonded to the container via a first adhesive, and a first wiring pattern provided such that the first bonding portion is disposed between the recess and the first wiring pattern in plan view.

The present application is based on, and claims priority from JP Application Serial Number 2023-066999, filed Apr. 17, 2023, the disclosure of which is hereby incorporated by reference herein in its entirety.

### BACKGROUND

### 1. Technical Field

The present disclosure relates to a resonator device.

### 2. Related Art

A temperature compensated oscillator includes a resonator element, and an integrated circuit having an oscillation circuit for oscillating the resonator element and a temperature compensation circuit. A high frequency accuracy can be achieved by temperature compensation of the integrated circuit for deviation of the oscillation frequency of the resonator element from a desired frequency within a predetermined temperature range. As an example of such a temperature compensated oscillator, JP-A-2022-30002 discloses an oscillator in which a first container accommodating a resonator element and an integrated circuit is accommodated in a second container to enhance inhibition of heat transfer to the resonator element in the first container, and achieve a higher frequency accuracy.

However, in the oscillator described in JP-A-2022-30002, the first container accommodating the resonator element and the integrated circuit is fixed to a fixing portion protruding toward the first container side from a recessed bottom surface of the second container with an adhesive. Hence, the adhesive fixing the first container spreads and increases the adhesive area, which may reduce the insulation property and degrade the frequency stability of the output oscillation frequency.

### SUMMARY

A resonator device includes a container accommodating a resonator component and a base substrate on which the container is mounted. The base substrate includes a recess overlapping the container in plan view and forming a space with the container, a first bonding portion overlapping the container in plan view and bonded to the container via a first adhesive, and a first wiring pattern provided such that the first bonding portion is disposed between the recess and the first wiring pattern in plan view.

### BRIEF DESCRIPTION OF THE DRAWINGS

FIG. 1 is a plan view illustrating a schematic configuration of a resonator device according to a first embodiment.

FIG. 2 is a cross-sectional view taken along line II-II of FIG. 1.

FIG. 3 is a cross-sectional view taken along line III-III of FIG. 1.

FIG. 4 is a plan view illustrating a schematic configuration of a base substrate included in the resonator device according to the first embodiment.

FIG. 5 is a plan view illustrating a schematic configuration of a resonator included in the resonator device according to the first embodiment.

FIG. 6 is a cross-sectional view taken along line VI-VI of FIG. 5.

FIG. 7 is a plan view illustrating a schematic configuration of a resonator device according to a second embodiment.

FIG. 8 is a cross-sectional view taken along line VIII-VIII of FIG. 7.

FIG. 9 is a plan view illustrating a schematic configuration of a base substrate included in a resonator device according to a third embodiment.

### DESCRIPTION OF EMBODIMENTS

### 1. First Embodiment

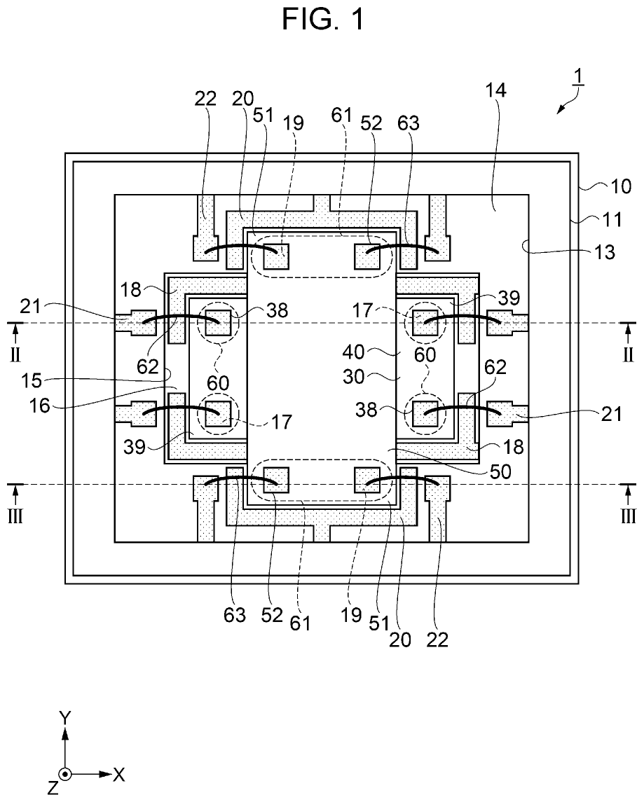

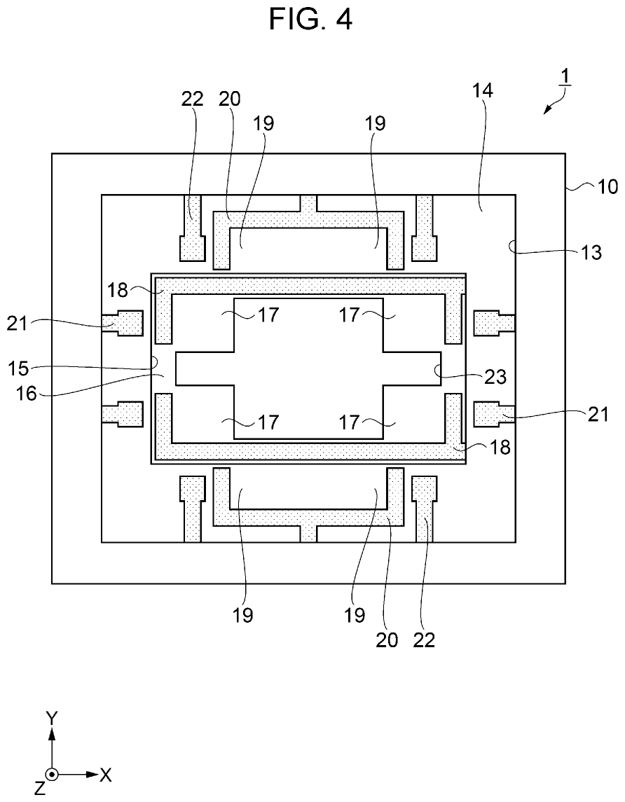

First, a resonator device 1 according to a first embodiment will be described with reference to FIGS. 1 to 6 by using a temperature compensated oscillator with a double-sealed structure as an example.

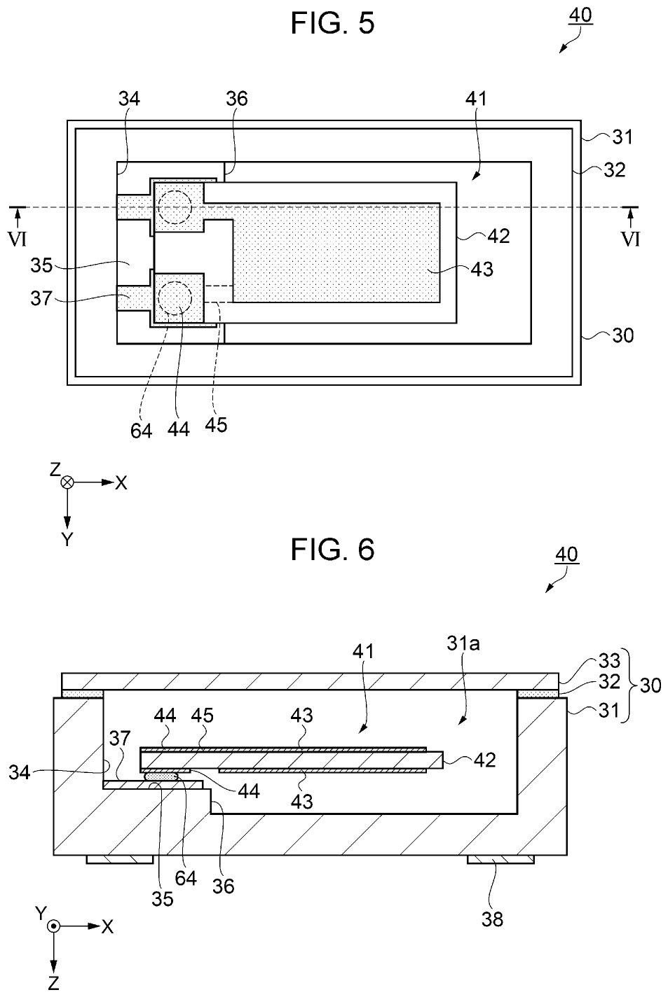

Note that in order to simplify the description of the internal configuration of the resonator device 1, FIG. 1 illustrates a state where a lid 12 is removed. In addition, in order to simplify the description of the internal configuration of a resonator 40, FIG. 5 illustrates a state where a lid 33 is removed.

Moreover, to simplify the description, an X axis, a Y axis, and a Z axis are shown as three axes orthogonal to one another in the following drawings. A direction along the X axis is referred to as “X direction”, a direction along the Y axis is referred to as “Y direction”, and a direction along the Z axis is referred to as “Z direction”. In each axial direction, the arrow tip end side is also referred to as “positive side”, and the base end side is also referred to as “negative side”.

As illustrated in FIGS. 1, 2, and 3, the resonator device 1 according to the present embodiment has the resonator 40 in which a resonator component 41 is accommodated in a container 30, an integrated circuit 50 having an oscillation circuit for oscillating the resonator component 41 and a temperature compensation circuit, and a base substrate 10 accommodating the resonator 40 and the integrated circuit 50.

As illustrated in FIGS. 5 and 6, the resonator 40 has the resonator component 41 and the container 30 accommodating the resonator component 41.

In the resonator component 41, an excitation electrode 43, a pad electrode 44, and a lead electrode 45 electrically coupling the excitation electrode 43 and the pad electrode 44 are formed at front and back main surfaces of a plate-shaped substrate 42.

The excitation electrode 43 is disposed in a central portion of the substrate 42, so that the excitation electrode 43 of the front main surface and the excitation electrode 43 of the back main surface overlap each other.

The pad electrode 44 is disposed on front and back main surfaces of an end portion of the substrate 42 on the negative side in the X direction. In addition, the pad electrode 44 electrically coupled to the excitation electrode 43 on the front main surface via the lead electrode 45 is disposed on an end portion on the negative side in the Y direction, and the pad electrode 44 electrically coupled to the excitation electrode 43 on the back main surface via the lead electrode 45 is disposed on an end portion on the positive side in the Y direction. Note that the pad electrodes 44 formed at the front and back main surfaces are electrically coupled to each other by a side-surface electrode (not illustrated).

Moreover, the resonator component 41 is accommodated in the container 30, and is bonded by a cantilever structure bonded only at the pad electrode 44 portion which is one end portion of the resonator component 41.

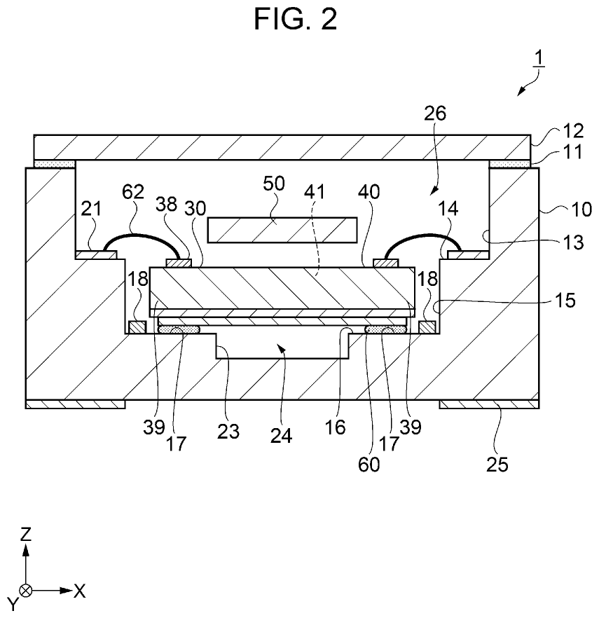

The container 30 is rectangular, and has a base 31 made of ceramic or the like, the lid 33 made of metal, ceramic, glass, or the like, and a bonding material 32 such as a seal ring and low-melting glass for bonding the base 31 and the lid 33. In addition, as illustrated in FIGS. 1 and 2, four corner portions 39 corresponding to the four corners of the container 30 are bonded to the base substrate 10 via a first adhesive 60.

The base 31 has a recess 34 open on the negative side in the Z direction and a recess 36 open on the negative side in the Z direction in a bottom surface 35 of the recess 34, and the recess 34 and the recess 36 form an accommodating space 31a for accommodating the resonator component 41. An internal terminal 37 is formed at the bottom surface 35 of the recess 34, and an external terminal 38 is formed at a side of the base 31 opposite to the lid 33 side. Note that the internal terminal 37 and the external terminal 38 are electrically coupled to each other by a through-silicone via (not illustrated) or the like. In addition, the accommodating space 31a is an airtight space and is filled with inert gas such as nitrogen, helium, and argon. However, the atmosphere in the accommodating space 31a is not particularly limited, and the accommodating space 31a may be depressurized or pressurized, for example.

Moreover, the resonator component 41 is bonded to the internal terminal 37 via a conductive bonding material 64. More specifically, the pad electrode 44 of the resonator component 41 is bonded with the bonding material 64 such as a conductive adhesive. Hence, the internal terminal 37 and the pad electrode 44 are electrically coupled to each other and apply pressure on the external terminal 38, so that the resonator component 41 can be oscillated.

Note that in the present embodiment, the base 31 made of ceramic or the like and the lid 33 made of metal, ceramic, glass, or the like are used as the container 30. However, the materials are not limited to these, and the base 31 made of silicone and the lid 33 made of silicone may be used.

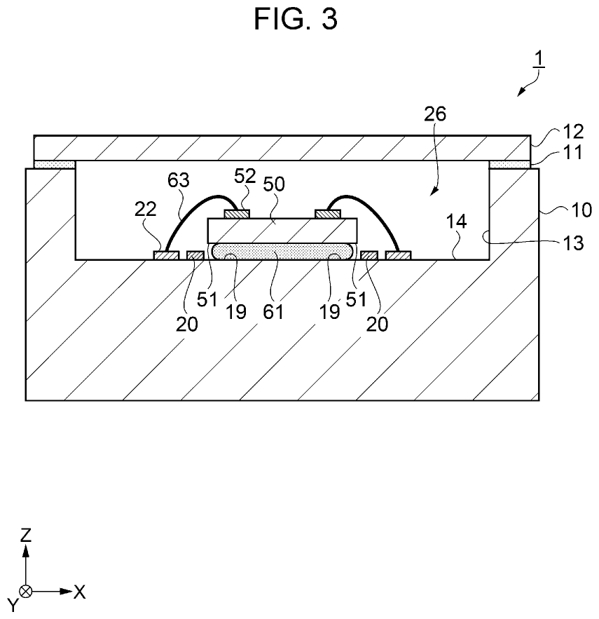

The integrated circuit 50 is rectangular, and has an oscillation circuit for oscillating the resonator component 41, and a temperature compensation circuit for performing temperature compensation to deal with deviation of the oscillation frequency of the resonator component 41 from a desired frequency within a predetermined temperature range. In addition, as illustrated in FIGS. 1 and 3, four corner portions 51 corresponding to the four corners of the integrated circuit 50 are bonded to the base substrate 10 via a second adhesive 61.

The base substrate 10 is made of ceramic or the like, and, together with the lid 12 made of metal, ceramic, glass, or the like, forms a package accommodating the resonator 40 and the integrated circuit 50. In addition, the base substrate 10 and the lid 12 are bonded via a bonding material 11 such as a seal ring and low-melting glass.

As illustrated in FIGS. 1, 2, 3, and 4, the base substrate 10 has a recess 13 open on the positive side in the Z direction and a recess 15 open on the positive side in the Z direction in a bottom surface 14 of the recess 13, and the recess 13 and the recess 15 form an accommodating space 26 for accommodating the resonator 40 and the integrated circuit 50. Accordingly, the accommodating space 26 overlaps the container 30 of the resonator 40 and the integrated circuit 50 in plan view. In addition, at a location on a bottom surface 16 of the recess 15 overlapping the container 30, a recess 23 open on the positive side in the Z direction is provided. The recess 23 overlaps the container 30 in plan view and forms a space 24 with the container 30. By providing the space 24 between the container 30 and the base substrate 10, heat transfer from the base substrate 10 to the container 30 is curbed and the insulation property of the container 30 can be enhanced.

The integrated circuit 50 is mounted on the bottom surface 14 of the recess 13, and the integrated circuit 50 is bonded, via the second adhesive 61, to a second bonding portion 19 of the bottom surface 14 overlapping a corner portion 51 of the integrated circuit 50 in plan view. Note that on the bottom surface 14, a second wiring pattern 20 is provided so as to sandwich the second bonding portion 19 with the accommodating space 26, specifically the recess 15, which overlaps the container 30 in plan view. In other words, the second wiring pattern 20 is provided such that the second bonding portion 19 is disposed between the second wiring pattern 20 and the accommodating space 26, specifically the recess 15, which overlaps the container 30 in plan view. The second wiring pattern 20 is an L-shaped pattern corresponding to the corner portion 51 of the integrated circuit 50, and is electrically coupled to the ground electrode. Since the second wiring pattern 20 is formed corresponding to the corner portion 51 of the integrated circuit 50, it can be used for positioning when mounting the integrated circuit 50, and variation in the adhesive area of the second adhesive 61 can be controlled.

In addition, the bottom surface 14 is provided with an internal wiring pattern 21 and an internal wiring pattern 22. The internal wiring pattern 21 is electrically coupled to the external terminal 38 formed in the container 30 via a bonding wire 62, and the internal wiring pattern 22 is electrically coupled to a terminal 52 formed in the integrated circuit 50 via a bonding wire 63. Note that the internal wiring pattern 21 and the internal wiring pattern 22 are electrically coupled to each other by an electrode pattern (not illustrated). In addition, the internal wiring pattern 22 is electrically coupled to an external terminal 25 provided on a surface of the base substrate 10 opposite to the lid 12 side by a through-silicone via (not illustrated).

The container 30 is mounted on the bottom surface 16 of the recess 15, and the container 30 is bonded, via the first adhesive 60, to a first bonding portion 17 of the bottom surface 16 overlapping the corner portion 39 of the container 30 in plan view. Note that on the bottom surface 16, a first wiring pattern 18 is provided so as to sandwich the first bonding portion 17 together with the recess 23 in plan view. In other words, a first wiring pattern 18 is provided such that the first bonding portion 17 is disposed between the first wiring pattern 18 and the recess 23 in plan view. The first wiring pattern 18 is an L-shaped pattern corresponding to the corner portion 39 of the container 30, and is electrically coupled to the ground electrode. Since the recess 23 and the first wiring pattern 18 surround the first bonding portion 17 that bonds the container 30, spreading of the first adhesive 60 is curbed and the adhesive area of the first adhesive 60 can be kept constant. As a result, the insulation property of the container 30 can be enhanced even more.

The resonator device 1 of the present embodiment has the recess 23 formed in a location overlapping the container 30 in plan view, allowing the space 24 to be provided between the container 30 and the resonator device 1. As a result, the insulation property of the container 30 can be enhanced. Moreover, since the first bonding portion 17 that bonds the container 30 is surrounded by the recess 23 and the first wiring pattern 18, spreading of the first adhesive 60 can be curbed. Hence, the adhesive area of the first adhesive 60 can be kept constant, and the insulation property of the container 30 can be enhanced even more. Accordingly, the resonator device 1 having a higher frequency accuracy can be obtained.

In addition, since the L-shaped first wiring pattern 18 and second wiring pattern 20 are provided along the corner portions 39 and 51 of the container 30 and the integrated circuit 50, the first wiring pattern 18 and the second wiring pattern 20 can be used for positioning when mounting the container 30 and the integrated circuit 50, whereby the container 30 and the integrated circuit 50 can be mounted with high precision.

### 2. Second Embodiment

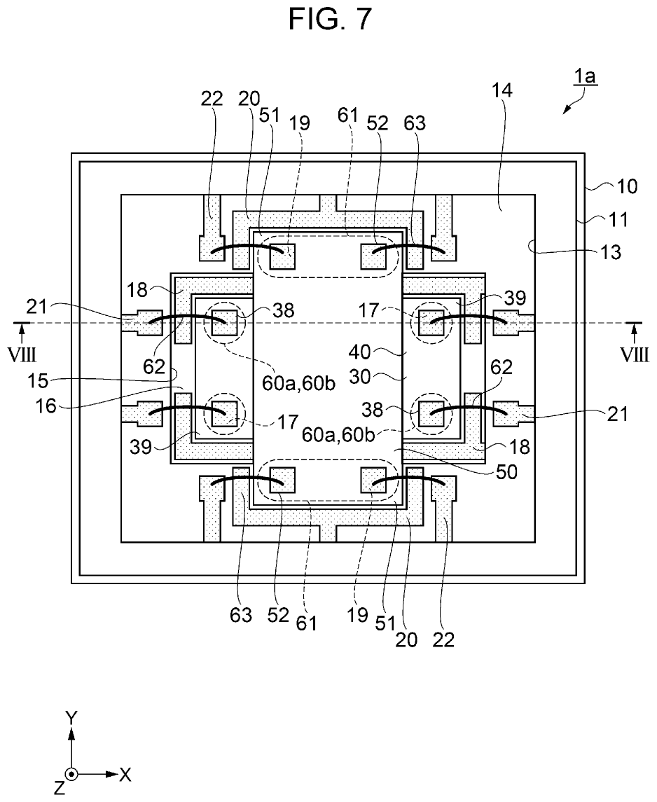

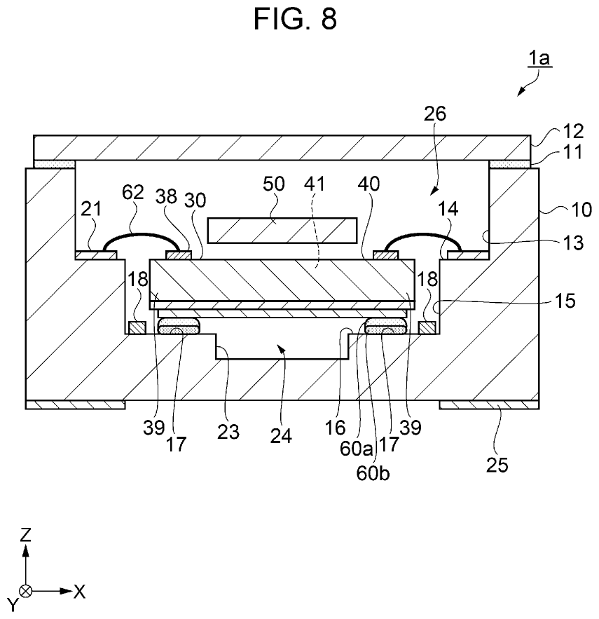

Next, a resonator device 1a according to a second embodiment will be described with reference to FIGS. 7 and 8. Note that in order to simplify the description, FIG. 7 illustrates a state where a lid 12 is removed.

The resonator device 1a of the present embodiment is similar to the resonator device 1 of the first embodiment, except that the shape of a first adhesive 60a that bonds a container 30 is different compared to the resonator device 1 of the first embodiment. Note that the following description focuses on differences from the aforementioned first embodiment, and omits description of similar matters.

As illustrated in FIGS. 7 and 8, in the resonator device 1a, the container 30 is bonded to a first bonding portion 17 via a bump member 60b formed at the first bonding portion 17 and a first adhesive 60a applied to the bump member 60b.

Since the resonator device 1a of the present embodiment has the bump member 60b disposed between the container 30 and the first bonding portion 17, the gap between the container 30 and the first bonding portion 17 can be made wider than in the resonator device 1 of the first embodiment. Hence, the insulation property of the container 30 can be enhanced even more. Moreover, since an L-shaped first wiring pattern 18 and second wiring pattern 20 are provided, an effect similar to that of the first embodiment can be obtained.

### 3. Third Embodiment

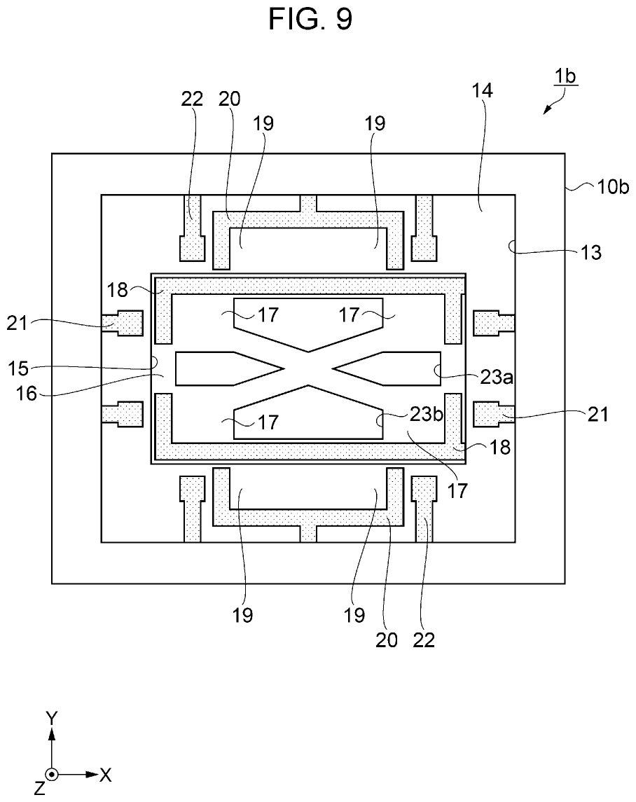

Next, a resonator device 1b according to a third embodiment will be described with reference to FIG. 9.

The resonator device 1b of the present embodiment is similar to the resonator device 1 of the first embodiment, except that the shapes of recesses 23a and 23b disposed in locations overlapping a container 30 are different compared to the resonator device 1 of the first embodiment. Note that the following description focuses on differences from the aforementioned first embodiment, and omits description of similar matters.

As illustrated in FIG. 9, in the resonator device 1b, the shapes of the recesses 23a and 23b disposed in locations overlapping the container 30 are pentagonal in plan view. The shape of the recess 23a is triangular on one side in the X direction, and the shape of the recess 23b is triangular on one side in the Y direction. Moreover, the triangular shapes of the recesses 23a and 23b are both disposed on the center side of a base substrate 10b.

Hence, diagonal first bonding portions 17 are continuous with each other at a bottom surface 16, which improves the strength of the base substrate 10b against warpage, i.e., deformation in the Z direction.

In the resonator device 1b of the present embodiment, the diagonal first bonding portions 17 are continuous with each other at the bottom surface 16 due to the recesses 23a and 23b disposed in locations overlapping the container 30. Hence, the strength of the base substrate 10b against deformation in the Z direction can be improved. Moreover, since an L-shaped first wiring pattern 18 and second wiring pattern 20 are provided, an effect similar to that of the first embodiment can be obtained.

What is claimed is:

1. A resonator device comprising
a container accommodating a resonator component and
a base substrate on which the container is mounted, wherein
the base substrate includes
a recess overlapping the container in plan view and forming a space with the container,
a first bonding portion overlapping the container in plan view and bonded to the container via a first adhesive, and
a first wiring pattern provided such that the first bonding portion is disposed between the recess and the first wiring pattern in plan view.

2. The resonator device according to claim 1, wherein
in plan view, the container is a rectangle having a corner portion bonded to the first bonding portion via the first adhesive, and
the first wiring pattern includes an L-shaped pattern provided corresponding to the corner portion.

3. The resonator device according to claim 1, wherein
the container is bonded to the first bonding portion via a bump member formed at the first bonding portion and the first adhesive applied to the bump member.

4. The resonator device according to claim 1, further comprising
an integrated circuit electrically coupled to the container, wherein
the base substrate includes a bottom surface on which the integrated circuit is mounted and an accommodating space formed at the bottom surface and overlapping the integrated circuit in plan view, and
the container is accommodated in the accommodating space.

5. The resonator device according to claim 4, wherein the base substrate includes
a second bonding portion overlapping the integrated circuit in plan view and bonded to the integrated circuit via a second adhesive, and
a second wiring pattern provided such that the second bonding portion is disposed between the accommodating space and the second bonding portion in plan view.

6. The resonator device according to claim 5, wherein
in plan view, the integrated circuit is a rectangle having a corner portion bonded to the second bonding portion via the second adhesive, and
the second wiring pattern includes an L-shaped pattern provided corresponding to the corner portion.
